(19) United States
(12) Patent Application Publication
(10) Pub. No.: US 2013/0105993 A1
(43) Pub. Date: May 2, 2013

(54) SEMICONDUCTOR DEVICE INTERCONNECT

(71) Applicants: Raj BAHADUR, Niskayuna, NY (US); David SHADDOCK, Niskayuna, NY (US); Binoy SHAH, Niskayuna, NY (US)

(72) Inventors: Raj BAHADUR, Niskayuna, NY (US); David SHADDOCK, Niskayuna, NY (US); Binoy SHAH, Niskayuna, NY (US)

(73) Assignee: GENERAL ELECTRIC COMPANY, Schenectady, NY (US)

(21) Appl. No.: 13/284,314

(22) Filed: Oct. 28, 2011

(51) Int. Cl. H01L 23/48; H01L 21/28

(52) U.S. Cl. 257/782; 438/666; 257/E23.01; 257/E21.158

(57) ABSTRACT

There is set forth herein a semiconductor assembly including an integrated circuit and a set of springs extending from the integrated circuit that can be adapted for connection to an external article. The external article can be e.g. an integrated circuit or a printed circuit board. On connection of the semiconductor assembly to an external article there can be defined a semiconductor assembly comprising the integrated circuit the set of springs and the external article. The set of springs can be metal nanospring array can formed by GLAD (Glancing angle deposition) process. In one embodiment, the nanospring array can be GLAD formed on a substrate and then applied to the integrated circuit. In one embodiment, the nanospring array can be GLAD formed on the integrated circuit.

### BACKGROUND

The disclosure relates to semiconductor devices in general and particularly to an interconnect for a semiconductor device.

Commercially available semiconductor devices employ a variety of different interconnect technologies. Leaded semiconductor devices feature lead plates having a series of leads or pins. For connecting to a circuit board the leads are pressed into a printed circuit board and soldered.

Flip chip semiconductor devices employ solder bumps and/or copper pillars for connection to an external article such as another semiconductor device or printed circuit board. A semiconductor integrated circuit can include a series of pads on an under surface thereof. Solder bumps are formed on the series of pads and then the integrated circuit can be flipped to interface with the external article. With solder bumps interfaced to an external article, the solder bumps can be re-melted to form an electrical connection with the external article. A mounted semiconductor integrated circuit can be subject to under-filling, the disposing of underfill material between the underside of the semiconductor integrated circuit and the external article. The underfill material can comprise an electrically insulative adhesive.

### SUMMARY

There is set forth herein a semiconductor assembly including an integrated circuit and a set of springs extending from the integrated circuit that can be adapted for connection to an external article. The external article can be e.g. an integrated circuit or a printed circuit board. On connection of the semiconductor assembly to an external article there can be defined a semiconductor assembly comprising the integrated circuit the set of springs and the external article. The set of springs can be metal nanospring array can formed by GLAD (Glancing angle deposition) process. In one embodiment, the nanospring array can be GLAD formed on a substrate and then applied to the integrated circuit. In one embodiment, the nanospring array can be GLAD formed on the integrated circuit.

In one embodiment there is set forth herein a semiconductor device assembly comprising a semiconductor integrated circuit having one or more interconnect interface;

one or more spring coupled with the one or more interconnect interface of the semiconductor integrated circuit, the one or more spring terminating in one or more distal end, the one or more spring being electrically conductive and defining one or more interconnect.

In one embodiment, there is set forth herein, a method for making a semiconductor device assembly, the method comprising providing a semiconductor device integrated circuit, the semiconductor device integrated circuit having one or more interconnect interface and coupling to the one or more interconnect interface of the semiconductor integrated circuit one or more electrically conductive spring, the one or more electrically conductive spring defining one or more interconnect.

In one embodiment, there is set forth herein a semiconductor device assembly comprising a semiconductor integrated circuit having a plurality of interconnect interfaces; a plurality of electrically conductive interconnects coupled with the plurality of interconnect interfaces of the semiconductor integrated circuit, the set of electrically conductive interconnects terminating in distal ends, the plurality of electrically conductive interconnects including a set of electrically conductive interconnects disposed within a region.

### BRIEF DESCRIPTION OF THE DRAWINGS

FIG. 1 is a cross sectional side schematic view of a semiconductor device assembly having an integrated circuit and a set of springs;

FIG. 2 is a cross sectional side schematic view of a semiconductor device assembly having an integrated circuit, an external article and a set of springs interposed between the integrated circuit and the external article;

FIG. 3 is a cross sectional side schematic view of a prior art semiconductor device assembly comprising solder bumps;

FIG. 4 is a perspective view of a copper substrate for illustrating a method for making a semiconductor device assembly;

FIG. 5 is a cross sectional side schematic view of a semiconductor device assembly (with nanosprings) being formed;

FIG. 6 is a cross sectional side schematic view of a semiconductor device assembly;

FIG. 7 is a perspective view of a silicon substrate for illustrating a method for making a semiconductor device assembly;

FIG. 8 is a cross sectional side schematic view of a semiconductor device assembly being formed;

FIG. 9 is a cross sectional side schematic view of a semiconductor device assembly;

FIG. 10 is a perspective view of a substrate including an integrated circuit on which springs can be grown using a GLAD process;

FIG. 11 is a cross sectional view and an appended top cross-sectional schematic view of a semiconductor device assembly having regions of higher interconnect densities aligned to integrated circuit areas of higher interconnect interface density, and regions of lower interconnect densities aligned to integrated circuit areas of lower interconnect interface density;

FIG. 12 is a cross sectional side view and an appended top cross sectional schematic view of a semiconductor device assembly having spring interconnects aligned to relatively higher thermal energy areas of an integrated circuit and non-spring interconnects aligned to relating lower thermal energy areas of an integrated circuit;

FIG. 13 is a diagram view illustrating a single stop deposition process;

FIG. 14 is a diagram view illustrating a multi-step deposition process.

In each of the cross-sectional schematic views herein, the cross section schematic views can be taken along a diagonal cross section of a cubic rectangular semiconductor chip assembly. The features described herein can be better understood with reference to the drawings described below. The drawings are not necessarily to scale, emphasis instead generally being placed upon illustrating the principles set forth herein. In the drawings, like numerals are used to indicate like parts throughout the various views.

### DETAILED DESCRIPTION

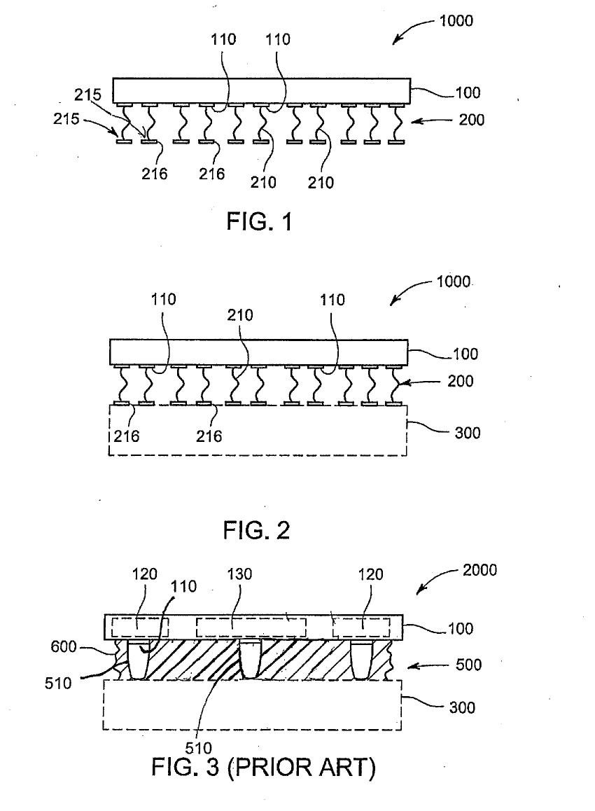

There is set forth herein as shown in FIG. 1a semiconductor device assembly 1000 comprising a semiconductor integrated circuit 100 and a set 200 of springs 210 extending from the semiconductor device integrated circuit 100 and terminating in distal ends 215 that can be connected to external article 300 (FIG. 2) external to the semiconductor integrated circuit 100. On connection of semiconductor assembly 1000 as shown in FIG. 1 to an external article 300 there can be defined a semiconductor device assembly 1000 including semiconductor integrated circuit 100 an external article 300 external to the semiconductor integrated circuit 100 and a set of springs 200 disposed between the semiconductor integrated circuit 100 and the external article 300.

In one embodiment, the external article 300 can be provided by an integrated circuit apparatus. In one embodiment the integrated circuit apparatus forming external article 300 can include pads formed in the manner of pads 110 interfaced to the set 200 of springs 210. In one embodiment, the integrated circuit apparatus forming external article 300 can include springs 210 formed in the manner of springs 210 interfaced to the set of springs 200. In a still further embodiment, the external article 300 can be provided by a printed circuit board.

In the development of semiconductor device assembly 1000 it was determined that prior art semiconductor assemblies can be subject to failure attributable to self heating of a semiconductor integrated circuit 100. A prior art semiconductor device assembly 2000 is shown in FIG. 3. Assembly 2000 can include a set 500 of solder bumps 510 and underfill 600 disposed between integrated circuit 100 and external article 300. In the development of assembly 2000 it was determined that semiconductor integrated circuit 100 can be susceptible to self heating. It was determined that self heating can be particularly prevalent in the case of particular applications including such application wherein integrated circuit 100 is implemented as a microprocessor integrated circuit. In the case integrated circuit 100 is provided by a microprocessor integrated circuit, integrated circuit 100 can include one or more processing “cores” defining core area hot spot area 120 that run hotter than a remainder of integrated circuit 100, such as portions of integrated circuit 100 including cache memory defining cache area cold spot 130.

While “hot spot” areas defined by cores and “cold spot” areas defined by cache are seen in microprocessor applications hot spots (relatively hotter areas) as well as cold spots (relatively colder areas) are seen in a variety of other integrated circuit applications. Hot spot areas may be alternatively termed areas of relatively high thermal energy. Cold spot areas may alternatively be termed areas of relatively low thermal energy. Processor cores and or other hot spot inducing circuitries and cold spot inducing circuitries exist in a variety of integrated circuits other than those that are microprocessor integrated circuit specific, e.g., power delivery integrated circuits interface microcontroller applications and memory applications. Underfill 600 of the prior art assembly 2000 can distribute loads attributable to thermal expansion resulting from self heating of integrated circuit 100 and can accordingly prevent or reduce a likelihood of cracking of assembly 2000.

In the development of semiconductor device assembly 1000 it was further determined that prior art semiconductor device assemblies cannot be expected to withstand thermal stresses attributable to self heating of integrated circuit 100. For example in the development of assembly 1000 it was determined that the assembly 2000 of the prior art (FIG. 3) can become unstable during self heating of integrated circuit 100. It was noted in the development of assembly 1000 that in prior art assembly 2000 (FIG. 3) there can be a mismatch in the relative coefficients of thermal expansion (CTE) between integrated circuit 100 and external article 300 (silicon die CTE˜2.5 ppm/k, copper spreader CTE˜17 ppm/k). Higher mismatches in CTE can be expected in the case a semiconductor integrated circuit 100 is connected to an external article 300 comprising a printed circuit board through a set of interconnects. Relatively lesser but still significant mismatches in CTE can be expected in the case semiconductor integrated circuit 100 is connected to an external article 300 comprising another integrated circuit through a set of interconnects.

According to one advantage of semiconductor device assembly 1000 springs 210 allow accommodation of stresses attributable to mismatched thermal expansion of integrated circuit 100 relative to external article 300 resulting from self heating of integrated circuit 100. According to another advantage, use of underfill 600 (FIG. 3) can be avoided. Underfill 600 which can be provided for distribution of loading attributable to thermal expansion resulting from self heating of integrated circuit 100 can be avoided when springs 210, which accommodate thermal expansion mismatched between integrated circuit 100 and article 300, are employed. Still further, because use of underfill 600 can be avoided, material cost of semiconductor device assembly 1000 can be reduced relative to assembly 2000. Still further, manufacturing problems associated with providing underfill 600 can be avoided. In the development of semiconductor device assembly 1000 it was determined that the distribution of underfill 600 in interior areas of semiconductor device assembly 1000 can be difficult and costly. With smaller pitch dimensions, processing times to provide underfill 600 using vacuum underfill processes or JET dispense underfill processes in excess of thirty minutes or hours have been observed. Still further, as use of underfill 600 can be avoided by the providing of assembly 1000, a spacing distance between interconnects can be reduced. Still further, springs 210 can be manufactured to have relatively smaller diameters than bumps 510. Accordingly, because of the spacing reduction advantage and the diameter reduction advantage, a number of interconnects per unit area (density of interconnects) and pitch (center to center spacing) of the interconnects can be with use of deposited columns as set forth herein which one embodiment can comprise springs.

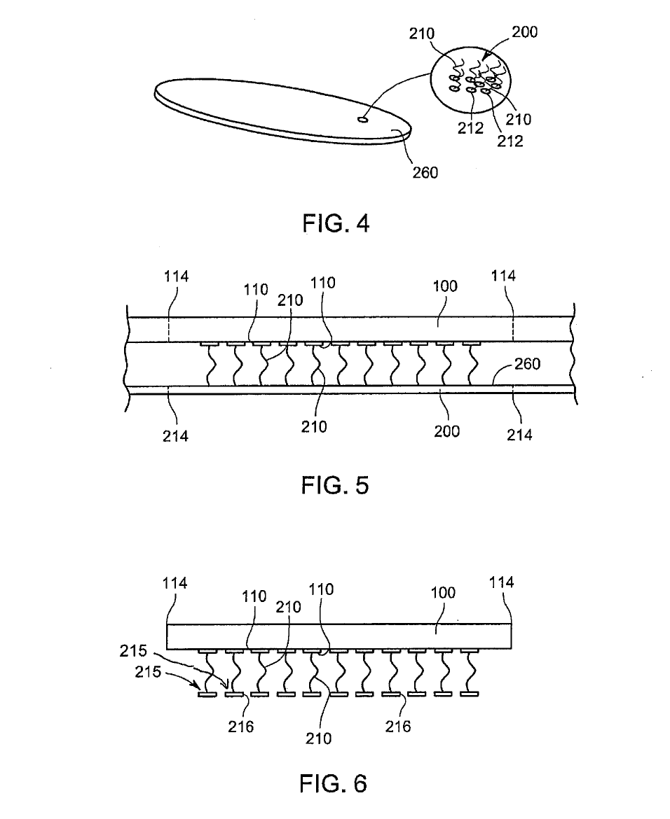

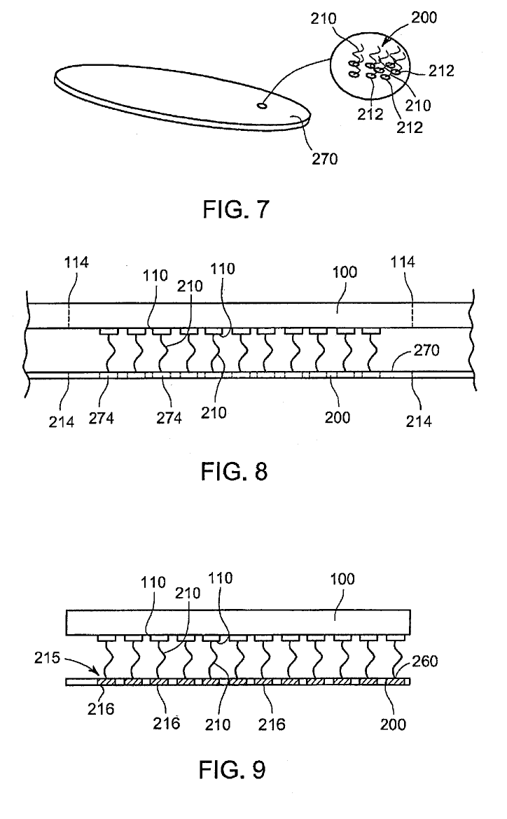

A variety of processes can be employed for formation of set 200 of springs 210. In one example set 200 of springs 210 can be formed by a GLAD process. Varieties of GLAD processes are described with reference to FIGS. 4 through 10. In the views of FIGS. 4 through 6, there is described a GLAD process wherein a set 200 of springs 210 are grown on a copper substrate 260 and then applied to semiconductor integrated circuit 100. In another embodiment as described in connection with FIGS. 7 through 9, a set 200 of springs 210 are grown on a silicon substrate 270 and then applied to a semiconductor integrated circuit. In another embodiment, a set of springs 200 are grown on semiconductor integrated circuit 100.

Referring to FIGS. 4 through 6, there is described a process wherein a 200 of springs 210 are grown on a copper substrate 260 and then applied to a semiconductor integrated circuit 100. With reference to FIG. 4 a copper substrate 260 an be provided and a set 200 of springs 210 can be grown on substrate. For growing of springs, a glancing angle deposition (GLAD) process can be utilized. Glancing angle deposition utilizes a flow of atoms or molecules from gas phase impinging on a substrate from an oblique angle in a vacuum which results in a deposited film showing a columnar morphology. A spring (helical) morphology can be achieved by rotating a substrate according to predefined cycles.

With springs formed on substrate 260, substrate 260 including a set of springs 200 can be coupled to integrated circuit 100. Integrated circuit 100 can include an array of pads 110 for receipt of springs 210. Substrate 260 can have springs 210 formed thereon in such a manner that a pattern of springs 210 matches a pattern of pads 110. Dashed lines 114, in the view of FIG. 5 indicates where copper substrate 260 including springs 210 and a wafer including several integrated circuits 100 are cut. For finishing a semiconductor device assembly including integrated circuit 100 and springs 210 copper material intermediate of springs 210 can be removed to define copper caps 212 at a distal end of the various springs 210. A finished semiconductor device assembly 1000 in a form adapted for connecting an external article 300 is shown in FIG. 6.

Referring to FIGS. 7 through 9, there is described a process wherein springs 210 are grown on a silicon (Si) substrate 270 and then applied to a semiconductor integrated circuit 100. With reference to FIG. 7, silicon (Si) substrate 270 can be provided and springs 210 can be grown on substrate 270. For growing of springs 210, a glancing angle deposition (GLAD) process can be utilized.

With springs 210 formed on substrate 270, substrate 270 including springs 210 can be coupled to integrated circuit 100. Integrated circuit 100 can include an array of pads 110 adapted for connection to springs 210. Substrate 270 can have springs 210 formed thereon in such manner that a pattern of springs matches a pattern of pads 110. Dashed lines 114, 214 in the view of FIG. 8 indicates where substrate 270 including springs 210 and a wafer including several integrated circuits 100 are cut. For finishing of the semiconductor device assembly 1000 including semiconductor integrated circuit 100 and springs 210 formed on substrate 270 vias 274 can be formed on substrate 270 and the vias 274 filled with metal to define caps 212 at the distal ends of springs 210 (FIG. 9), substrate 270 can be maintained as part of semiconductor device assembly 1000 or else can be removed.

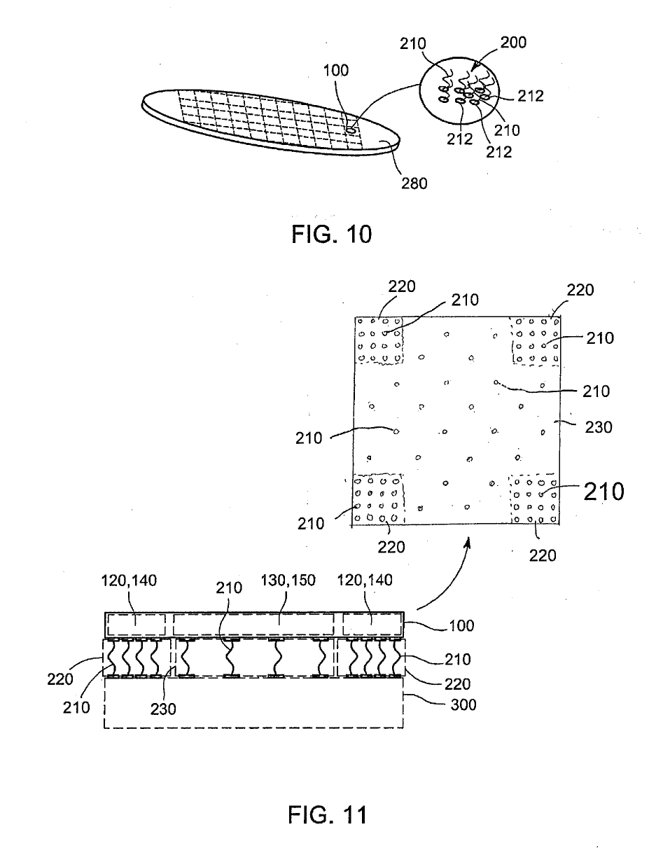

Referring to FIG. 10, there is described a process wherein springs 210 are grown on a semiconductor integrated circuit 100. With reference to FIG. 10 a silicon (Si) substrate 280 including integrated circuit 100 can be provided and springs 210 can be grown on substrate 280.

For growing of springs 210, on a substrate, e.g., substrate 260, substrate 270, substrate 280a glancing angle deposition (GLAD) process can be utilized. It has been mentioned that a pattern 200 of springs 210 can be provided to match a pattern of pads 110 of semiconductor integrated circuit 100.

For coupling one or more springs 210 onto integrated circuit 100, springs 210 can be GLAD formed on one or more interconnect interface of integrated circuit 100. The one or more interconnect interface can be defined by one or more pad 110. Whether springs 210 are grown on substrate 260, substrate 270, or substrate 280, a positioning on springs 210 can be controlled by controlling a position of nucleation centers of the substrate. A size of an interconnect can depend on a size of a nucleation center. Nucleation centers can be formed by depositing a polystyrene colloid film on a monolayer which comprises domains and depletion areas. Colloid defects can be defined in the depletion areas. The defects can serve as nucleation centers during glancing angle deposition (GLAD).

A cross sectional shape and morphology of interconnects grown using GLAD can be controlled by controlling GLAD input controls including oblique angle of deposition and substrate positional control. A cross-sectional shape of a GLAD formed column can be controlled by controlling an angle of incidence by controlling a ratio of a deposition rate to a substrate rotation rate. Column morphology can be controlled e.g., to form spring shaped (helical) columns as set forth in various embodiments herein. In other embodiments, columns formed as interconnects can be cylindrical or matchstick in morphology.

In the examples set forth herein springs 210 can be of nanometer scale. In one example, springs 210 can have diameters of less than 100 nm, and in one embodiment less than 500 nm. In one embodiment, a set of springs 200 can have a pitch of less than 5,000 nm.

In the view of FIG. 1, and in the embodiments described with reference to FIGS. 4-6 and FIGS. 7-9 distal end 215 of springs 210 can be delimited by caps 216. In another embodiment, distal ends 215 of one or more springs 210 can be devoid of caps 216. Regarding further details of semiconductor device assembly 1000 as set forth in various views, pads 110 of semiconductor integrated circuit 100 can be formed by electroplating deposition.

In one example interconnects between semiconductor integrated circuit 100 and external article 300 are provided entirely by springs 210. In another example interconnects between semiconductor integrated circuit 100 and external article 300 can comprise both spring a non-spring interconnects, e.g., one or more spring 210 and one or more bump 510.

In the development of semiconductor device assembly 1000 it was determined that integrated circuit 100 can have one or more first area 140 of a greater density of interconnect interfaces which can be delimited by pads 110 and one or more second area 150 of lesser density of interconnect interfaces delimited by pads 110. While integrated circuit 100 can have one or more interconnect interface defined by one or more pad 110, integrated circuit 100 can include one or more interconnect interface devoid of one or more pad 110. Area 140 can also define a core area hot spot area 120 and area 150 can also define a cache area cold spot area 130. Area 120 is accordingly co-labeled area 140 and area 130 is accordingly co-labeled area 150. In the embodiment of FIG. 11, springs 210 are formed in one or more first regions 220 of relatively higher density that can be aligned to area 120, 140 and one or more second region 230 of relatively lesser density aligned to area 120, 140 of semiconductor integrated circuit 100.

Various embodiments of assembly 1000 in accordance with FIG. 11 are set forth in Table A. In one example of the embodiment set forth in Table A each spring interconnect can have a common diameter, and each region can be characterized by a uniform pitch and density.

TABLE A

| | Region 220 | | | | | | | |
|---|---|---|---|---|---|---|---|---|
| | | | | Cross | | | | |
| | | | | sectional area | | | | |
| | | | | extending | Region 230 | | | |
| | | | | transversely | | | | Cross |
| | | | | through the | | | | sectional area |
| | | | | interconnects | | | | extending |
| | | | | (for each | | | | transversely |
| | Average | Average | Average | instance of the | Average | Average | Average | through the |
| Embodiment | diameter | density | pitch | four instances) | diameter | density | pitch | interconnects |
| A | 10 nm | 2.5e12 | 0.5 um | 16 mm2 | 5 um | 1.13e10 | 5 um | 21 mm2 |
| B | 50 nm | 9.79e10 | 2.5 um | 16 mm2 | 25 um | 4.53e8 | 25 um | 21 mm2 |
| C | 100 nm | 2.44e10 m2 | 5 um | 16 mm2 | 50 um | 1.132e8 m2 | 50 um | 21 mm2 |
| D | 200 nm | 6.24e9 m2 | 10 um | 16 mm2 | 70 um | 5.8e7 m2 | 70 um | 21 mm2 |
| D | 550 nm | 1.51e9 m2 | 20 um | 16 mm2 | 80 um | 4.4e7 m2 | 80 um | 21 mm2 |
| F | 800 nm | 6e8 | 32 um | 16 mm2 | 110 um | 2.3e7 | 110 | 21 mm2 |
| G | 1200 | 2.6e8 | 48 um | 16 mm2 | 130 um | 1.7e7 | 130 | 21 mm2 |

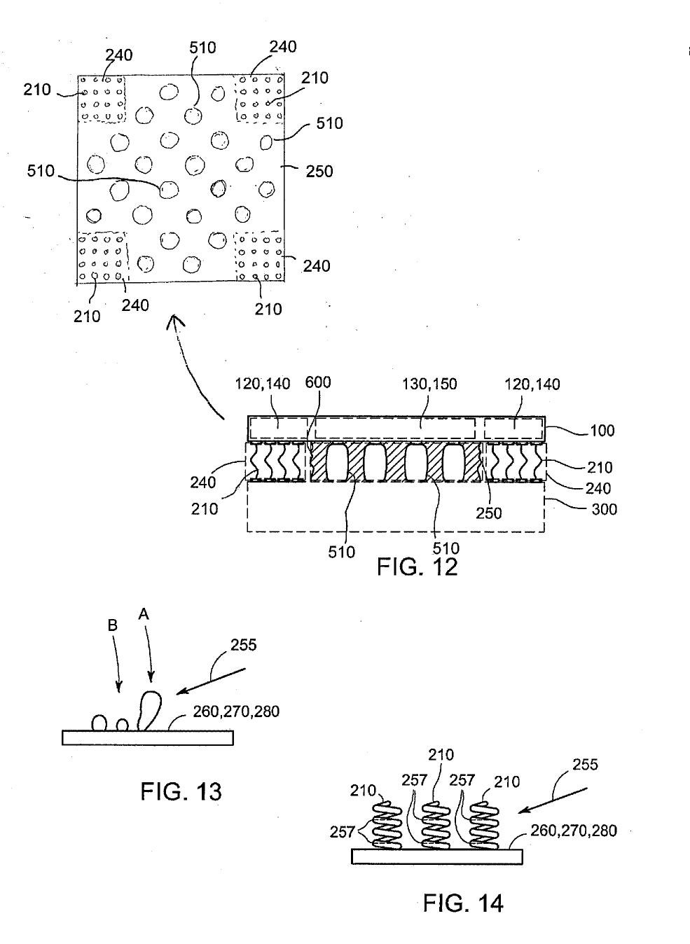

In the development of semiconductor device assembly 1000 it was determined that semiconductor integrated circuit 100 can have one or more area 120 of relatively higher interconnect density e.g., a core area and one or more area 140 of relatively lower interconnect density. In the development of assembly 1000 it was determined that assembly 1000 can be provided to include spring interconnects 210 of one or more region aligned to the areas 120 of higher interconnect density and non-spring interconnects (e.g., solder bumps 510 and or copper pillars) aligned to areas of relatively lower interconnect density, e.g., CACHE, northbridge area. Solder bumps 510 can be replaced by copper pillars in one example of an alternative non-spring interconnect. In the embodiment of FIG. 12 assembly 1000 includes springs 210 disposed in one or more region 240 aligned to one or more area 120 of relatively higher interconnect density and bumps 510 disposed in region 250 aligned to one or more area 130 of relatively lower interconnect density. In the examples, alignment can be provided by disposing one or more interconnect so that it is directly under a particular area. In the embodiment of FIG. 12, a core area 120 can define a higher density interconnect interface area 140 a cache area 130 can define a lower density interconnect interface area 150. There is set forth herein a semiconductor device assembly, wherein the semiconductor integrated circuit includes one or more area of relatively higher interconnect density and one or more region of relatively lower interconnect density, the set of springs being aligned to the one or more area of relatively higher interconnect density, the semiconductor device assembly having non-spring electrical interconnect apparatus disposed between the semiconductor integrated circuit and the external apparatus aligned to the one or more relatively lower interconnect density regions of the semiconductor integrated circuit.

Various embodiments of assembly 1000 in accordance with FIG. 12 are set forth in Table B. In one example of the embodiment set forth in Table B each spring interconnect can have a common diameter, and each region can be characterized by a uniform pitch and density.

TABLE B

| | Region 240 | | | | | | | |
|---|---|---|---|---|---|---|---|---|
| | | | | Cross | | | | |
| | | | | sectional area | | | | |
| | | | | extending | Region 250 | | | |
| | | | | transversely | | | | Cross |
| | | | | through the | | | | sectional area |
| | | | | interconnects | | | | extending |
| | | | | (for each | | | | transversely |
| | Average | Average | Average | instance of the | Average | Average | Average | through the |
| Embodiment | diameter | density | pitch | four instances) | diameter | density | pitch | interconnects |
| A | 10 nm | 2.5e12 | 0.5 um | 16 mm2 | 40 um | 5.3e7 | 90 um | 35 mm2 |
| B | 50 nm | 9.79e10 | 2.5 um | 16 mm2 | 50 um | 3.5e7 | 110 um | 35 mm2 |
| C | 100 nm | 2.44e10 m2 | 5 um | 16 mm2 | 80 um | 2.2e7/m2 | 130 um | 35 mm2 |
| D | 200 nm | 6.24e9 m2 | 10 um | 16 mm2 | 110 um | 2.3e7 | 110 um | 35 mm2 |
| E | 550 nm | 1.51e9 m2 | 20 um | 16 mm2 | 200 um | 5.85e6/m2 | 230 um | 35 mm2 |
| F | 800 nm | 6e8 | 32 um | 16 mm2 | 350 um | 1.397e6/m2 | 500 um | 35 mm2 |
| G | 1200 | 2.6e8 | 48 um | 16 mm2 | 500 um | 6.3e5 | 500 um | 35 mm2 |

In one embodiment of assembly 1000 it was determined that a spacing distance and pitch of interconnects as may be provided by springs 210 can be decreased by halting deposition of the columns during GLAD. Referring to FIG. 13 it can be observed that over-growth of a first column provided by a spring 210 at location “A”, in formation can “shadow” to prevent proper formation of a column provided by a spring 210 at location “B” with an incident evaporation beam being in the direction of arrow 255. For reducing the likelihood of column failure attributable to over-growth resulting from a shadow effect, a multi-step deposition process can be utilized. In a multi-step deposition process deposition, e.g., through GLAD, GLAD can be halted one or more times during a deposition of material forming a column, e.g., a column in the form of a spring 210. Referring to FIG. 14, dashed lines 257 indicate growth stop and start locations attributable to GLAD, GLAD being sequentially performed starting with first location exposed for short height spring growth and then adjusting angle to expose only the adjacent location for deposition growth until all the locations are grown a short height exposure. Thereafter restarting with the first layer to further increase the height of the spring. This will help in achieving a reduced pitch of the springs. Columns provided by springs 210 can be GLAD formed utilizing a variety of metals e.g., copper, aluminum, tungsten and titanium. Springs 210 can be electrically conductive.

A small sample of systems methods and apparatus that are described herein is as follows:
A1. A semiconductor device assembly comprising:

a semiconductor integrated circuit having one or more interconnect interface;

one or more spring coupled with the one or more interconnect interface of the semiconductor integrated circuit, the one or more spring terminating in one or more distal end, the one or more spring being electrically conductive and defining one or more interconnect.
A2. The semiconductor device assembly of A1, wherein the semiconductor device assembly further includes external article coupled to the one or more distal end and wherein the external article comprises an integrated circuit apparatus.
A3. The semiconductor device assembly of A1, wherein the integrated circuit apparatus includes one or more pad interfaced to the one or more spring.
A4. The semiconductor device assembly of A2, wherein the integrated circuit apparatus includes one or more spring interfaced to the one or more spring.
A5. The semiconductor device assembly of A1, wherein the semiconductor device assembly further includes an external article coupled with the one or more distal end and wherein the external article comprises a printed circuit board.
A6. The semiconductor device assembly of A1, wherein the one or more spring includes a set of springs disposed in a region wherein the set of springs have an average diameter of not more than 550 nm, and an average pitch of not more than 30 μm.
A7. The semiconductor device assembly of A1, wherein the semiconductor integrated circuit includes one or more area of relatively high thermal energy and one or more area of relatively low thermal energy, the one or more spring including one or more spring aligned to the one or more area of relatively higher thermal energy, the semiconductor device assembly having one or more non-spring electrical interconnect aligned to the one or more relatively lower thermal energy area of the semiconductor integrated circuit.
A8. The semiconductor device assembly of A7, wherein the one or more area of relatively high thermal energy comprises a core area of the semiconductor integrated circuit.
A9. The semiconductor device assembly of A1, wherein the one or more interconnect interface include one or more pad.
A10. The semiconductor device assembly of A1, wherein the semiconductor device assembly further comprises an external article comprising a printed circuit board.
B1. A method for making a semiconductor device assembly, the method comprising:

providing a semiconductor device integrated circuit, the semiconductor device integrated circuit having one or more interconnect interface; and

coupling to the one or more interconnect interface of the semiconductor integrated circuit to one or more electrically conductive spring, the one or more electrically conductive spring defining one or more interconnect.
B2. The method of B1, wherein the method further includes forming the one or more electrically conductive spring by GLAD.
B3. The method of B1, wherein the method further includes forming the one or more electrically conductive spring by glancing angle deposition (GLAD).
B4. The method of B1, wherein the method further includes forming the one or more electrically conductive spring by glancing angle deposition (GLAD) using a copper substrate.
B5. The method of B1, wherein the method further includes forming the one or more electrically conductive spring by glancing angle deposition (GLAD) using a silicon substrate.
B6. The method of B1, wherein the coupling includes GLAD forming the one or more electrically conductive spring on the one or more interconnect interface.
B7. The method of B1, wherein the method further includes forming the one or more electrically conductive spring using a multi-step glancing angle deposition (GLAD) process wherein deposition is halted and restarted during formation of the one or more spring.
B8. The method of B1, wherein the method further includes GLAD forming the one or more spring on an external substrate and wherein the coupling includes interfacing the one or more spring formed on the external substrate to the one or more interconnect interface.
B9. The method of B1, wherein the method further includes GLAD forming the one or more spring on an external substrate using glancing angle deposition (GLAD) and wherein the coupling includes interfacing the one or more spring formed on the external substrate to the one or more interconnect interface.
B10. The method of B1, wherein the method further includes GLAD forming the one or more spring on an external metal substrate using glancing angle deposition (GLAD) and wherein the coupling includes interfacing the one or more spring formed on the external substrate to the one or more interconnect interface.
B11. The method of B1, wherein the method further includes GLAD forming the one or more spring on an external silicon substrate using glancing angle deposition (GLAD) and wherein the coupling includes interfacing the one or more spring formed on the external substrate to the one or more interconnect interface.
C1. A semiconductor device assembly comprising:

a semiconductor integrated circuit having a plurality of interconnect interfaces;

a plurality of electrically conductive interconnects coupled with the plurality of interconnect interfaces of the semiconductor integrated circuit, the set of electrically conductive interconnects terminating in distal ends, the plurality of electrically conductive interconnects including a set of electrically conductive interconnects disposed within a region, wherein the set of electrically conductive interconnects disposed within the region have an average diameter on not more than 500 nm and an average pitch of not more than 20 um.
C2. The semiconductor device assembly of C1, wherein the region extends a cross sectional area delimited by the semiconductor integrated circuit.
C3. The semiconductor device assembly of C1, wherein the semiconductor device assembly includes a further region, the further region having a set of electrically conductive interconnects disposed therein, the set of electrically conductive interconnects disposed in the further region having an average pitch different from an average pitch of the set of electrically conductive interconnects disposed in the region.
C4. The semiconductor device assembly of C1, wherein the plurality of electrically conductive interconnects are of spring morphology.
C5. The semiconductor device assembly of C1, wherein the region has a cross sectional area of greater than 1.0 mm2, wherein the set of electrically conductive interconnects disposed within the region have an average diameter of not more than 200 nm and an average pitch of not more than 10 um.
C6. The semiconductor device assembly of C1, wherein the region has a cross sectional area of greater than 1.0 mm2, wherein the set of electrically conductive interconnects disposed within the region have an average diameter of not more than 100 nm and an average pitch of not more than 5 um.
C7. The semiconductor device assembly of C1, wherein the set of electrically conductive interconnects disposed within the region have an average diameter of not more than 50 nm and an average pitch of not more than 2.5 um.
C8. The semiconductor device assembly of C1, wherein the set of electrically conductive interconnects disposed within the region have an average diameter of not more than 10 nm and an average pitch of not more than 0.5 um.

While the present invention has been described with reference to a number of specific embodiments, it will be understood that the true spirit and scope of the invention should be determined only with respect to claims that can be supported by the present specification. Further, while in numerous cases herein wherein systems and apparatuses and methods are described as having a certain number of elements it will be understood that such systems, apparatuses and methods can be practiced with fewer than or greater than the mentioned certain number of elements. Also, while a number of particular embodiments have been described, it will be understood that features and aspects that have been described with reference to each particular embodiment can be used with each remaining particularly described embodiment.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the various embodiments without departing from their scope. While the dimensions and types of materials described herein are intended to define the parameters of the various embodiments, they are by no means limiting and are merely exemplary. Many other embodiments will be apparent to those of skill in the art upon reviewing the above description. The scope of the various embodiments should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure. It is to be understood that not necessarily all such objects or advantages described above may be achieved in accordance with any particular embodiment. Thus, for example, those skilled in the art will recognize that the systems and techniques described herein may be embodied or carried out in a manner that achieves or optimizes one advantage or group of advantages as taught herein without necessarily achieving other objects or advantages as may be taught or suggested herein.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

We claim:

1. A semiconductor device assembly comprising:
a semiconductor integrated circuit having one or more interconnect interface;
one or more spring coupled with the one or more interconnect interface of the semiconductor integrated circuit, the one or more spring terminating in one or more distal end, the one or more spring being electrically conductive and defining one or more interconnect.

2. The semiconductor device assembly of claim 1, wherein the semiconductor device assembly further includes external article coupled to the one or more distal end and wherein the external article comprises an integrated circuit apparatus.

3. The semiconductor device assembly of claim 2, wherein the integrated circuit apparatus includes one or more pad interfaced to the one or more spring.

4. The semiconductor device assembly of claim 2, wherein the integrated circuit apparatus includes one or more spring interfaced to the one or more spring.

5. The semiconductor device assembly of claim 1, wherein the semiconductor device assembly further includes an external article coupled with the one or more distal end and wherein the external article comprises a printed circuit board.

6. The semiconductor device assembly of claim 1, wherein the one or more spring includes a set of springs disposed in a region wherein the set of springs have an average diameter of not more than 550 nm, and an average pitch of not more than 30 um.

7. The semiconductor device assembly of claim 1, wherein the semiconductor integrated circuit includes one or more area of relatively high thermal energy and one or more area of relatively low thermal energy, the one or more spring including one or more spring aligned to the one or more area of relatively higher thermal energy, the semiconductor device assembly having one or more non-spring electrical interconnect aligned to the one or more relatively lower thermal energy area of the semiconductor integrated circuit.

8. The semiconductor device assembly of claim 7, wherein the one or more area of relatively high thermal energy comprises a core area of the semiconductor integrated circuit.

9. The semiconductor device assembly of claim 1, wherein the one or more interconnect interface include one or more pad.

10. The semiconductor device assembly of claim 1, wherein the semiconductor device assembly further comprises an external article comprising a printed circuit board.

11. A method for making a semiconductor device assembly, the method comprising:
providing a semiconductor device integrated circuit, the semiconductor device integrated circuit having one or more interconnect interface; and
coupling to the one or more interconnect interface of the semiconductor integrated circuit to one or more electrically conductive spring, the one or more electrically conductive spring defining one or more interconnect.

12. The method of claim 11, wherein the method further includes forming the one or more electrically conductive spring by GLAD.

13. The method of claim 11, wherein the method further includes forming the one or more electrically conductive spring by glancing angle deposition (GLAD).

14. The method of claim 11, wherein the method further includes forming the one or more electrically conductive spring by glancing angle deposition (GLAD) using a copper substrate.

15. The method of claim 11, wherein the method further includes forming the one or more electrically conductive spring by glancing angle deposition (GLAD) using a silicon substrate.

16. The method of claim 11, wherein the coupling includes GLAD forming the one or more electrically conductive spring on the one or more interconnect interface.

17. The method of claim 11, wherein the method further includes forming the one or more electrically conductive spring using a multi-step glancing angle deposition (GLAD) process wherein deposition is halted and restarted during formation of the one or more spring.

18. The method of claim 11, wherein the method further includes GLAD forming the one or more spring on an external substrate and wherein the coupling includes interfacing the one or more spring formed on the external substrate to the one or more interconnect interface.

19. The method of claim 11, wherein the method further includes GLAD forming the one or more spring on an external substrate using glancing angle deposition (GLAD) and wherein the coupling includes interfacing the one or more spring formed on the external substrate to the one or more interconnect interface.

20. The method of claim 11, wherein the method further includes GLAD forming the one or more spring on an external metal substrate using glancing angle deposition (GLAD) and wherein the coupling includes interfacing the one or more spring formed on the external substrate to the one or more interconnect interface.

21. The method of claim 11, wherein the method further includes GLAD forming the one or more spring on an external silicon substrate using glancing angle deposition (GLAD) and wherein the coupling includes interfacing the one or more spring formed on the external substrate to the one or more interconnect interface.

22. A semiconductor device assembly comprising:
a semiconductor integrated circuit having a plurality of interconnect interfaces;
a plurality of electrically conductive interconnects coupled with the plurality of interconnect interfaces of the semiconductor integrated circuit, the set of electrically conductive interconnects terminating in distal ends, the plurality of electrically conductive interconnects including a set of electrically conductive interconnects disposed within a region, wherein the set of electrically conductive interconnects disposed within the region have an average diameter on not more than 500 nm and an average pitch of not more than 20 um.

23. The semiconductor device assembly of claim 22, wherein the region extends a cross sectional area delimited by the semiconductor integrated circuit.

24. The semiconductor device assembly of claim 22, wherein the semiconductor device assembly includes a further region, the further region having a set of electrically conductive interconnects disposed therein, the set of electrically conductive interconnects disposed in the further region having an average pitch different from an average pitch of the set of electrically conductive interconnects disposed in the region.

25. The semiconductor device assembly of claim 22, wherein the plurality of electrically conductive interconnects are of spring morphology.

26. The semiconductor device assembly of claim 22, wherein the region has a cross sectional area of greater than 1.0 mm2, wherein the set of electrically conductive interconnects disposed within the region have an average diameter of not more than 200 nm and an average pitch of not more than 10 um.

27. The semiconductor device assembly of claim 22, wherein the region has a cross sectional area of greater than 1.0 mm2, wherein the set of electrically conductive interconnects disposed within the region have an average diameter of not more than 100 nm and an average pitch of not more than 5 um.

28. The semiconductor device assembly of claim 22, wherein the set of electrically conductive interconnects disposed within the region have an average diameter of not more than 50 nm and an average pitch of not more than 2.5 um.

29. The semiconductor device assembly of claim 22, wherein the set of electrically conductive interconnects disposed within the region have an average diameter of not more than 10 nm and an average pitch of not more than 0.5 um.
